(19) United States
(12) Patent Application Publication
(10) Pub. No.: US 2011/0084406 A1
(43) Pub. Date: Apr. 14, 2011

(54) DEVICE AND INTERCONNECT IN FLIP CHIP ARCHITECTURE

(75) Inventors: Joo-Young CHOI, Fellbach (DE); Stefan Koch, Oppenweiler (DE)

(73) Assignee: Sony Corporation, Tokyo (JP)

(21) Appl. No.: 12/896,375

(22) Filed: Oct. 1, 2010

(30) Foreign Application Priority Data
Oct. 13, 2009 (EP) 09172922.8

(51) Int. Cl. H01L 23/48

(52) U.S. Cl. 257/778; 257/E23.01

(57) ABSTRACT

The present invention discloses a device in flip chip architecture. The device comprises at least two integrated circuits, which are interconnected by a passive device. The integrated circuits are mounted on a base ground plate, and are each connected to the passive device via conductive elements.

For the interconnection of the integrated circuits with the passive device, the device employs the structure of an inverted microstrip line, a suspended microstrip line, a covered microstrip line or a conventional microstrip line.

Depending on the interconnection scheme, low transmission loss, low susceptibility to external interferences, easy alignment properties in the assembly process, a compact package size, a high reproducibility and/or low cost can be achieved.

This invention discloses an interconnect in flip chip architecture. In particular this invention relates to a device, in which two or more chips or substrates are interconnected by a passive device, employing a structure resembling microstrip lines.

Integrated circuits, ICs or ‘chips’, are formed of a single piece of semiconductor wafer, and each chip can contain tens of millions of interconnected semiconductor circuits or passive elements. With recent technological advances in semiconductor processing technology, like for example drastic improvements of lithography tools, it became possible to substantially downsize ICs. As a benefit of the downsizing, the cost per IC could be steadily reduced, because production wafers yield more chips, and the operational speed of the ICs could be greatly increased, without an increase in power consumption.

As an example for high speed ICs, millimeter-wave monolithic integrated circuits, MIMICs, operate in a frequency range of about 30 to 300 GHz, and are mainly used for communication or sensing, because high operating frequencies allow wider bandwidth or higher resolutions, respectively.

However, ever further improvements of speed performance and lower production costs are necessary for an ongoing success of such chips. Highly integrated systems, in which several millimeter-wave circuits are combined inside one package, can lower manufacturing costs. Since additionally one of the biggest concerns of high frequency devices is still the minimization of transition losses caused by discontinuities of interconnections, new interconnection schemes between plural MIMICs in a packaged semiconductor device have become of great interest.

A widely used technique for connecting chips in a package is wire bonding. The chips require special bond-pads, and usually a gold wire connects the bond-pads with contacts on a mounting substrate. From there the signals are led to the outside of the package. This technique, however, has two great disadvantages. Firstly, since the chips are mounted with their structured surface facing away from the mounting substrate, the bond wires need to have a certain length, which limits the compactness of the package. Secondly, long bond wires introduce high inductance and parasitic interconnections in high frequency applications, which trigger signal loss and reduce signal quality.

Another approach for connecting chips in a package is the flip chip technique. Thereby, the structured surface of the chips faces a mounting substrate. The connection between the chips and the mounting substrate is realized by conducting elements, for example soldered or golden ball bumps can be used. These shorter bump connections have the advantage of low loss, low inductance and low parasitics, allowing for higher signal speeds. Additionally, the package size and the assembly costs can be reduced with the flip chip architecture.

Due to the mentioned advantages, the flip chip technique is the preferred technique for MIMICs. Transmission schemes within a single MIMIC chip employ inverted microstrip line, IMSL, structures to further reduce transmission losses. Since, however, in semiconductor devices, in which several MIMIC chips are integrated with passive devices (e.g., transmission lines, band-pass filters, couplers or power dividers), the path in the passive device is often longer than in the MIMIC chips, the overall low loss benefit thereof is not remarkable.

Simple interconnection schemes between MIMIC chips still use conventional wire bonding. However, discontinuities are a problem, and coupling through the air, causing unwanted feedback or oscillations, can occur due to the large wire inductances. Furthermore, conventional interconnection schemes suffer from a high susceptibility to external interference.

The objective problem of the present invention is therefore to provide a cheap and improved interconnection scheme between at least two MIMIC chips or millimeter-wave circuits in a packaged device.

The present invention solves the problem with a device in flip chip architecture, in which an interconnection scheme that resembles MSL is chosen for the interconnection between the MIMIC chips or millimeter-wave circuits.

In the main embodiment of the invention, the device in flip chip architecture comprises a base ground plate connected to ground, at least two chips mounted on the base ground plate, and a passive device comprising at least a conducting line, which is formed on a surface of a dielectric substrate. The passive device is connected to each of the chips through at least one conductive element.

The device thus employs the advantages of MSL structures for the interconnection of the MIMICs with the passive device. The interconnections can be manufactured at low cost and with high reproducibility. Moreover, MSL structures allow a more compact packaging of the device than conventional interconnection techniques. The MSL structure can be easily realized for MIMIC chips already utilizing a grounded coplanar waveguide structure, GCPW, technology, in which the chips are already mounted onto a grounded plate. Moreover, conventional ball bumping processes of the flip chip architecture can still be exploited, in order to create the conducting elements. The passive devices can be replaced at need, and the arrangement of the chips can be revised by changing the length of the passive device. The structure thus provides more flexibility than conventional interconnection schemes.

Preferably, the surface of the conducting line faces the surface of the chips.

In this case, the interconnection scheme resembles an inverted microstrip line, IMSL, structure. In such a face-down configuration, the conducting line has a low susceptibility to any external interference. Furthermore, no via holes have to be drilled through the dielectric substrate to connect the conducting elements and the conducting line. The fact that no vias have to be used reduces fabrication costs and signal loss. As another advantage, in comparison with other MSL structures, IMSL structures show improved low loss characteristics, because the electromagnetic field mostly existing in the air does not suffer from the dielectric loss. Since there is only one ground plate present in the device, also no unwanted parallel plate modes between ground plates occur.

All in all, the IMSL structure is the best structure in terms of high frequency characteristics and fabrication simplicity.

In another embodiment, the surface of the conducting line faces away from the surface of the chips.

Thus, the passive device resembles a suspended MSL structure. Transmission losses are low in such a structure, and in addition the signal line on top is easy to access for characterization or fine tuning. Furthermore, unwanted plate modes are impossible, because only one base ground plate is used.

In another embodiment, the passive device further comprises a second ground plate, which is formed on the surface of the dielectric substrate opposite to the surface, on which the conducting line is formed. The surface of the conducting line faces the surface of the chips.

This interconnection scheme resembles a covered MSL structure. Due to the face-down configuration and the additional cover, the conducting line has a very low susceptibility to any external interference.

In another embodiment the passive device further comprises a second ground plate, which is formed on the surface of the dielectric substrate opposite to the surface, on which the conducting line is formed. The surface of the conducting line faces away from the surface of the chips.

This interconnection scheme resembles a normal MSL structure, which can be manufactured at very low cost and with a high reproducibility. The signal line on top is easy to access for characterization or fine tuning, as other embodiments previously described.

Preferably a podium structure is additionally made on the base ground plate between the at least two chips, and below the passive device. The podium structure is short circuited with the base ground plate, but not necessarily in contact with the passive device.

The podium structure provides an electrical barrier enhancing isolation. A wide range of impedances of the conducting line can be easily achieved with such a podium structure. Since the impedance depends on the distance between the conducting line and the podium structure, changing the podium height directly controls the impedance. Very low characteristic impedances can be realized without leading to “too wide line width” versus the wavelength X. On the other hand side, very high characteristic impedances can be realized without coming to the limit of “too narrow line width” versus etching capability.

Preferably the ground base plate and the podium structure are formed from a single piece.

Thus, the manufacturing process can be simplified and made cheaper.

The podium structure can have a convex and/or concave shape or can have a tapered shape.

Different impedance distributions in the passive device can thus be realized. For a convex shape, the impedance is lower at the edges of the line, for a concave shape the impedance is lower in the center of the passive device.

Preferably, the dielectric substrate of the passive device is transparent to visible light.

In case of the above mentioned embodiments, in which only a dielectric substrate and a conducting line form the passive device, a transparent substrate greatly simplifies the alignment of the conducting line with the conducting elements, because the conductive elements are not hidden by the dielectric substrate.

Preferably, the transparent dielectric substrate is made of Quartz.

Quartz can tolerate wide temperature gradients and high heat rates in the manufacturing process. Furthermore, its purity allows a low contamination environment required for achieving high wafer yields. The dielectric constant of Quartz is suited to realize the claimed devices.

In another embodiment, the passive device further comprises any kind of passive elements/circuit (e.g. filters, couplers or power dividers).

Preferably, the passive device further comprises a virtual ground structure for compensating the terminated ground. Any conventional ground plane placed on the passive devices can degrade performances (e.g. by causing parallel plate modes, etc.), if it were not for additional solutions. The shape of the virtual ground structures can vary.

Signal quality can be improved with such virtual ground structures, by eliminating signal distortion due to reflections. This also reduces transmission losses.

The present invention will be described in more detail below, in reference to the attached drawings, wherein:

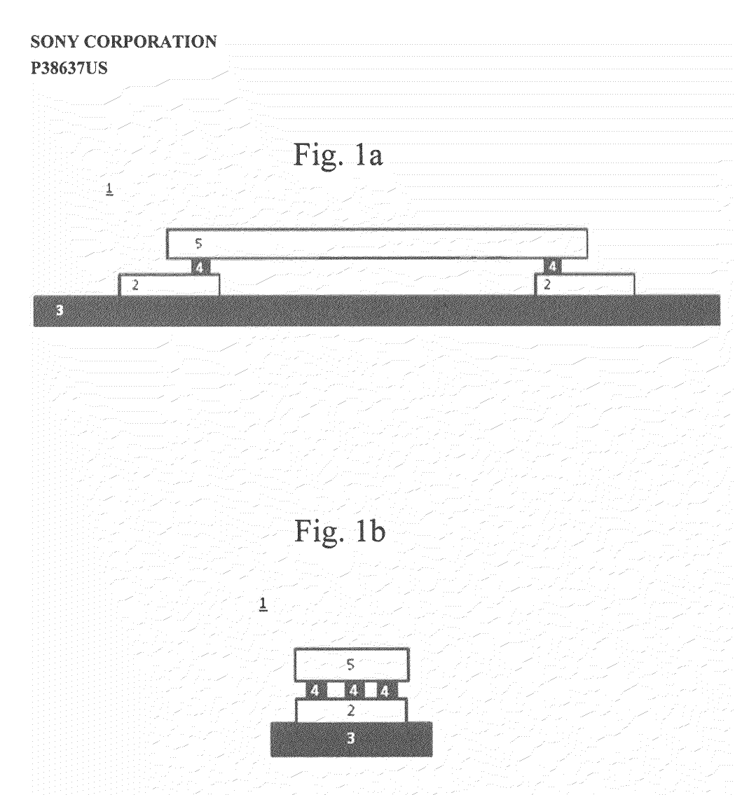

FIG. 1a shows the basic assembly of a device, in which two chips are connected via conductive elements to a passive device.

FIG. 1b shows a front view of the device from FIG. 1a.

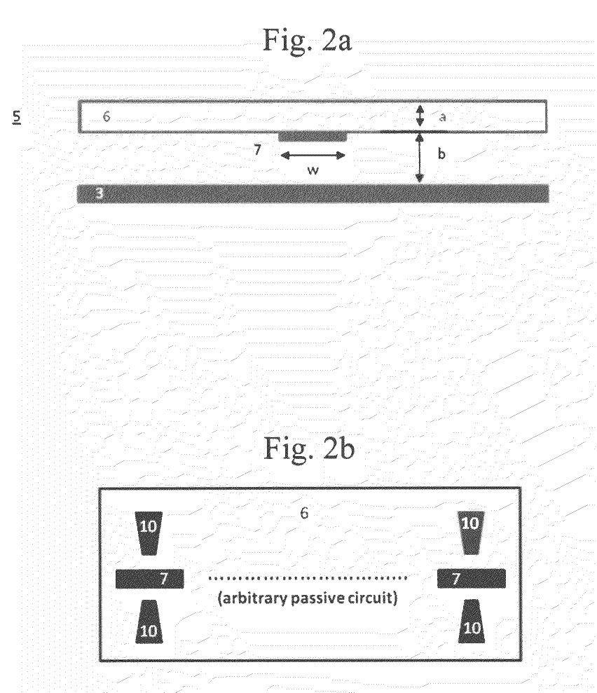

FIG. 2a shows how the passive device, which comprises a dielectric substrate and a conductive line, forms an IMSL structure with the ground plate.

FIG. 2b shows an example of a passive device with a virtual ground structure

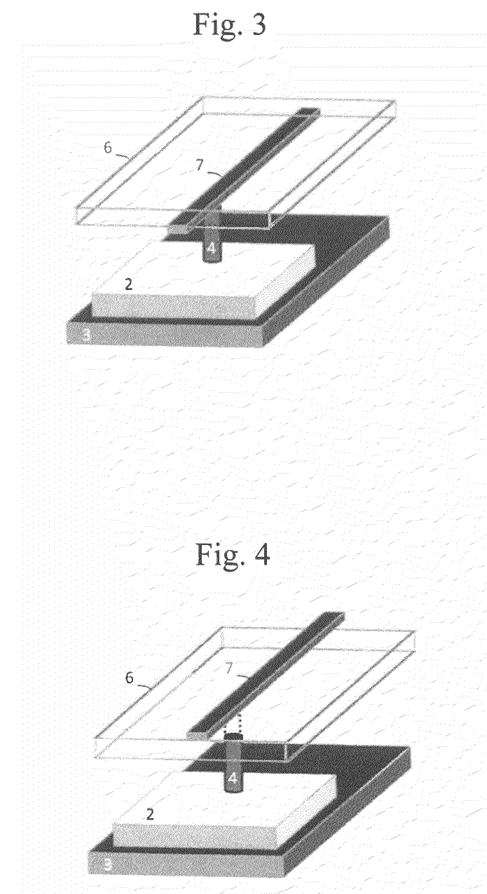

FIG. 3 shows a complete picture of a device having an IMSL structure.

FIG. 4 shows a complete picture of a device having a suspended MSL structure.

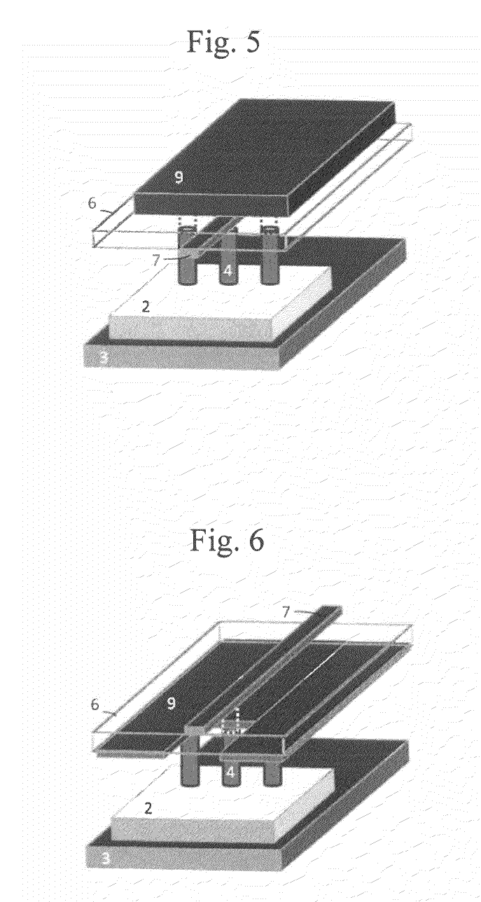

FIG. 5 shows a complete picture of a device having a covered MSL structure.

FIG. 6 shows a complete picture of a device having a MSL structure.

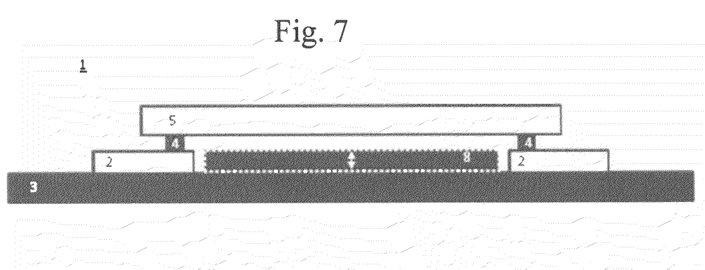

FIG. 7 shows a complete picture of a device comprising a podium structure.

FIG. 1a, together with FIG. 2, shows a basic assembly of a device 1 claimed by the present invention. At least two chips 2 are mounted onto a base ground plate 3. The invention is specially designed for GCPW MIMIC chips. However, any type of chips can replace the MIMIC chips for other purposes. The base ground plate 3 is conductive, preferably metallic, and is connected to ground. For instance, aluminum or copper are commonly used materials for semiconductor processes. However, also highly doped semiconductor layers or a general printed circuit board, PCB, as carrier board could be used as the ground base plate 3. The carrier board can include additional circuits or multi-layer structures on/in it.

Each chip 2 is connected to a passive device 5 by at least one conductive element 4. As conductive elements 4, for example, ball bumps can be established with state of art ball bumping processes. The conductive elements could for instance be soldered. Solder bumps show a high reliability and are widely used. However, some process challenges arise with solder bumps. Alternatively, bumps can be made from gold, which offer a superior conductivity over solder bumps. Gold ball bumps can, for example, be manufactured with commercially available ball wire bonders. The conductive elements of the present invention are, however, not limited to these types. Also the shape of the conductive elements 4 is not important, thus round ball shapes, but also rectangular or other shapes are possible.

FIG. 1b shows a front view of the device, demonstrating an example how more than one conductive elements could be arranged. More than one conductive elements can enhance mechanical stability.

The passive device 5 comprises at least a conducting line 7 and a dielectric substrate 6. Depending on the material of the dielectric substrate 6, and on the geometric shapes of the dielectric substrate 6 and the conducting line 7, the properties of the passive device 5 (e.g. characteristic impedance) can vary. Since the passive device 5 is connected to both chips 2, it effectively provides an interconnection thereof In its simplest form, the passive device 5 is a transmission line. However in other embodiments, the passive device 5 can be a filter, a coupler, a power divider, or any other passive circuit(s).

In FIG. 2a, as an example, the transmission line is shown for the passive device 5, comprising the dielectric substrate 6 and the conductive line 7. Together with the base ground plate 3, the transmission line of FIG. 2 forms an IMSL structure. In FIG. 3 a device 1 having the IMSL structure from FIG. 1 is shown. The surface of the conducting line 7 thereby faces the upper surface of the chips 2.

The width w of the conductive line 7, the thickness a of the dielectric substrate 6, the dielectric constant εᵣ of the dielectric substrate 6, and the distance b between the dielectric substrate 6 and the base ground plate 3 are free parameters. Depending on these parameters, different characteristic impedances Z₀ can be obtained for the transmission line. An appropriate design of the characteristic impedance Z₀ is important, because a mismatch of impedances at connection points of transmission lines will cause reflections and signal loss. For example, for a 50 Ohm transmission line, a typical value used in electric signaling, with a=150 μm and εᵣ=3.8, values of w=185 μm and b=50 μm were calculated.

The passive device preferably comprises a virtual ground structure 10 for compensating the terminated ground. The structure can be symmetrical as shown in FIG. 2b, but can also be asymmetrical. With a proper termination, reflections can be avoided, thus leading to a higher quality of the signal, especially at high frequencies.

As shown in FIG. 3, the conductive line 7 is directly connected to the conductive elements 4. Since the dielectric substrate is not between chip 2 and conductive line 7, no via holes have to be drilled. Thus, fabrication costs are reduced. Furthermore, since the dielectric substrate 6 shields the conductive line 7 from the outside world, the susceptibility to external interferences is small. Depending on the material used for the dielectric substrate 6 (i.e. its dielectric constant εᵣ), the shielding effect can be stronger or weaker. Because only the base ground plate 3 is present to form the IMSL structure, no unwanted parallel plate modes (between more than one ground plate) degrades the signal. The IMSL structure furthermore exploits all advantages of common MSL structures: it is easily fabricated, cheap and can yield compact package sizes.

It is advantageous to use a transparent material for the dielectric substrate 6. A transparent substrate allows an easy alignment of the conductive line 7 with the conductive elements 4. If the dielectric substrate 6 is not transparent and additional measures for alignment are not taken, misalignments during the respective process (e.g. a ball bumping process) can occur, because the conductive elements 4 are hidden. It has been shown, that such misalignment limits the performance of the device 1.

As a preferred material for a transparent dielectric substrate 6, Quartz was identified. Quartz has a dielectric constant, which yields reasonable parameters a, b and w (see FIG. 2). Furthermore, very thin Quartz substrates are available (down to 150 μm).

Finally, Quartz can tolerate wide temperature gradients and high heat rates in the manufacturing process and possesses a high purity allowing for a low contamination environment. A clean environment during the manufacturing process increases the wafer yields (i.e. how many functional chips can be processed on one wafer). However, the present invention is not limited to the use of Quartz as the dielectric substrate 6.

In FIG. 4, another embodiment of the present invention is shown. The device 1 resembles a suspended MSL structure. The surface of the conducting line 7 thereby faces away from the surface of the chips 2. At least one via (indicated by the dotted line) per chip has to be drilled through the dielectric substrate 6, in order to connect the conductive line 7 and the conductive element 4. The suspended MSL structure has low loss properties and can be very easily fabricated. In addition the signal line on top is easy to access for characterization or fine tuning. Since only the ground plate beneath the chip is present, no unwanted parallel plate modes occur.

In FIG. 5, another embodiment of the present invention is shown. The device 1 resembles a covered MSL structure. The surface of the conducting line 7 thereby faces towards the surface of the chips 2. Two vias (indicated by the dotted lines) have to be drilled through the dielectric substrate 6, in order to connect the ground of each chip with the second covering ground plate 9 via conductive elements 4. The covered MSL structure provides a very efficient shielding from external interference. Firstly, because the conductive line 7 is fashioned in a face-down configuration. Secondly, because the covering grounded plate 9 provides an excellent shielding against radiation from the outside of the device 1.

In FIG. 6, another embodiment of the present invention is shown. The device 1 resembles a normal MSL structure. The surface of the conducting line 7 thereby faces away from the surface of the chips 2. At least one via (indicated by the dotted lines) per chip has to be drilled through the dielectric substrate 6, in order to connect the chips with the conductive line 7 via conductive elements 4. The MSL structure provides a reasonable interconnection between two chips. The signal loss characteristics are superior to wire bonding techniques.

Another preferred aspect of the present invention is shown in FIG. 7. The device 1 (here having the IMSL structure) additionally comprises a podium structure 8, which is disposed on the base ground plate 3. The podium structure 8 is located between the at least two chips 2, and below the passive device 5. The podium structure 8 is short circuited with the base ground plate 3, thus is also connected to ground. No direct contact, however, is established between the podium structure 8 and the passive device 5, the chips, or the conductive elements 4.

Preferably the podium structure is metallic. It and can be fabricated from the same material as the base ground plate 3. The base ground plate 3 can also be structured in such a way, that the podium is part of the base ground plate, i.e. the podium structure 8 and the base ground plate 3 are formed from a single piece.

The podium structure effectively reduces the distance b between the dielectric substrate 6 and the base ground plate 3. The characteristic impedance of the passive device can thus be tailored. Very high characteristic impedances can be achieved with a low podium height, and very low characteristic impedances can be achieved with a very high podium height, i.e. with a small value of b.

Both cases can be achieved without changing the width w of the conductive line. Therefore, scenarios in which the width w gets too narrow and causes problems in etching processes can be prevented on the one hand side, and scenarios in which the width w gets too wide compared to the wavelength can be prevented on the other hand side. A wide impedance range is easily achievable with a podium structure 8.

The podium structure 8 of FIG. 7 is flat and parallel to the surface of the base ground plate 3, but can be also formed in a convex or concave shape. Thus, an uneven distribution of characteristic impedances can be achieved from the edge to the center of the passive device 5. More flexibility can thus be obtained especially when including more complex circuits than a transmission line in the passive device 5.

In summary, a device 1 in flip chip architecture has been presented. Four interconnection schemes were laid out, which are all suitable for GCPW MIMIC chips. The interconnection can be realized by a passive device, like a transmission line. By exploiting an IMSL, MSL, covered MSL, or suspended MSL structure, various advantages are realized. The interconnections can be chosen for a low transmission loss, a low susceptibility to external interference, easy alignment in the contacting process, compact package size, high reproducibility and low cost.

1. A device in flip chip architecture comprising
a base ground plate connected to ground;
at least two chips mounted on the base ground plate;
a passive device comprising at least a conducting line formed on a surface of a dielectric substrate, the passive device being connected to each of the chips through at least one conductive element.

2. A device according to claim 1, wherein
the surface of the conducting line faces the surface of the chips.

3. A device according to claim 1, wherein
the surface of the conducting line faces away from the surface of the chips.

4. A device according to claim 1, wherein
the passive device further comprises a second ground plate formed on the surface of the dielectric substrate opposite to the surface on which the conducting line is formed, and
the surface of the conducting line faces the surface of the chips.

5. A device according to claim 1, wherein
the passive device further comprises a second ground plate formed on the surface of the dielectric substrate opposite to the surface on which the conducting line is formed, and
the surface of the conducting line faces away from the surface of the chips.

6. A device according to claim 1, further comprising
a podium structure made on the base ground plate between the at least two chips and below the passive device, the podium structure being short circuited with the base ground plate, but not in contact with the passive device.

7. A device according to claim 6, wherein
the ground base plate and the podium structure are formed from a single piece.

8. A device according to claim 6 or 7, wherein
the podium structure has a convex shape.

9. A device according to claim 6 or 7, wherein
the podium structure has a concave shape.

10. A device according to claim 6 or 7, wherein
the podium structure has a tapered shape.

11. A device according to claim 1, wherein
the dielectric substrate is transparent to visible light.

12. A device according to claim 11, wherein
the dielectric substrate is made of Quartz.

13. A device according to claim 1, wherein
the passive device further comprises elements to form at least one passive circuit such as a filter, coupler or power divider.

14. A device according to claim 1, wherein
the passive device further comprises a virtual ground structure for compensating the terminated ground.

15. A device according to claim 14, wherein
the virtual ground structure has a symmetric structure.

16. A device according to claim 14, wherein
the virtual ground structure has an asymmetric structure.

17. A device according to claim 1, wherein
the ground base plate is a carrier board including additional circuit components on it.

18. A device according to claim 1, wherein
the ground base plate is a carrier board including multi-layer structures in it.
